(19) United States
(12) Patent Application Publication
(10) Pub. No.: US 2020/0227581 A1
(43) Pub. Date: Jul. 16, 2020

(54) GaAs Multi-Junction Solar Cell and Methods of Preparing Thereof

(71) Applicant: Yangzhou Changelight Co. Ltd., Yangzhou (CN)

(72) Inventors: Zhenlong WU, Yangzhou (CN); Wei JIANG, Yangzhou (CN); Yu WANG, Yangzhou (CN); Xiaoya HAN, Yangzhou (CN); Shilei DU, Yangzhou (CN)

(73) Assignee: Yangzhou Changelight Co. Ltd., Yangzhou (CN)

(21) Appl. No.: 16/290,681

(22) Filed: Mar. 1, 2019

(30) Foreign Application Priority Data
Jan. 14, 2019 (CN) 201910032207.X

(51) Int. Cl. H01L 31/0725; H01L 31/0336; H01L 31/054; H01L 31/18

(52) U.S. Cl. CPC H01L 31/0725; H01L 31/0336; H01L 31/028; H01L 31/18; H01L 31/054

(57) ABSTRACT

The present disclosure relates to a novel multi junction solar cell comprising a unique distributed Bragg reflector (DBR) layer, and methods of using and manufacturing the novel multi-junction solar cell. This disclosure further relates to the technical field of solar cells, and in particular to a lattice matched multi junction solar cell. For the lattice-matched multi junction solar cell, the application of the present disclosure can improve the wavelength uniformity and doping uniformity of the middle and top subcells and improve the photoelectric performance of the solar cell.

### CROSS REFERENCE TO RELATED APPLICATION

This application claims benefits of Chinese Patent Applications No. 201910032207.X, filed on Jan. 14, 2019 in the State Intellectual Property Office of China, the disclosure of which is incorporated herein by reference in its entirety.

### TECHNICAL FIELD

The present disclosure relates to a novel multi junction solar cell comprising a unique distributed Bragg reflector (DBR) layer, and methods of using and manufacturing the novel multi-junction solar cell. This disclosure further relates to the technical field of solar cells, and in particular to a lattice matched multi junction solar cell. For the lattice-matched multi junction solar cell, the present disclosure may improve the wavelength uniformity and doping uniformity of the middle and top subcells and improve the photoelectric performance of the solar cell.

### BACKGROUND

Solar cells convert solar energy directly into electricity, making it the most effective form of clean energy. With their high conversion efficiency (about 2 times that of Si solar cells), excellent radiation resistance, stable temperature characteristics and easy scale production, GaAs multi junction solar cells have completely replaced Si solar cells to become the main power source of the spacecraft. The GaInP/InGaAs/Ge solar cell, which is the representative solar cell of GaAs multi junction solar cells, has become the leader in solar cell conversion efficiency because the GaInP/InGaAs/Ge solar cell can provide more than 30% and 40% of conversion efficiency at an extraterrestrial spectrum (AM0) and at a ground high-concentration condition (AM1.5D, 500×), respectively.

In 2011, Takamoto et al. found that when about addition 1% of indium (In) is added to the GaAs solar subcell of a GaInP/InGaAs/Ge multi junction solar cell to match the lattice of the multi-junction solar cell, the conversion efficiency of multi junction solar cell can be effectively improved. In 2000, Stringfellow et al. found that adding a surfactant (such as Sb) to the GaInP material of the growth top cell or changing the growth conditions to change the degree of disorder of GaInP, the open circuit voltage and performance of the solar cell may be effectively improved.

Under an extraterrestrial space environment, the performance of a GaInP/InGaAs/Ge multi junction solar, especially the InGaAs middle subcell, may be affected due to the current density decrease caused by the irradiation damage when the GaInP/InGaAs/Ge multi junction solar cell is exposed to particle irradiations. When a distributed Bragg reflector (DBR) layer is introduced into the middle subcell, more sunlight can be reflected into the middle subcell by the DBR layer to provide a relatively high current density. In addition, the thickness of the base region of the middle subcell may be reduced thereby improving the radiation resistance features of the multi junction solar cell.

Especially for large-sized wafers, since the thermal expansion coefficient of InGaAs material is smaller than that of Ge, when the InGaAs material is epitaxially grown on the Ge substrate, tensile stress is generated with the increase of the temperature to cause the epitaxial wafer to be concave. Therefore, there is temperature difference between the wafer center and the wafer edge. Such temperature difference may lead to a difference of the degree of disorder of GaInP, and therefore may affect the wavelength uniformity and doping uniformity of the middle and top subcells, and thus may affect the photoelectric performance of the solar cell chip.

### SUMMARY

The present disclosure relates to a novel multi junction solar cell comprising a unique distributed Bragg reflector (DBR) layer, and methods of using and manufacturing the novel multi-junction solar cell.

In a first aspect, the present disclosure provides a multi junction solar cell comprising: a first bottom solar subcell; a second middle solar subcell; a third top solar subcell; a distributed Bragg reflector (DBR) layer, wherein the distributed Bragg reflector (DBR) layer is positioned immediately below the second middle solar subcell; a first tunnel junction positioned between the first bottom solar subcell and the distributed Bragg reflector (DBR) layer; and a second tunnel junction positioned between the second middle solar subcell and the third top solar subcell. The distributed Bragg reflector (DBR) layer has an average lattice parameter greater than the lattice parameter of the second middle solar subcell. Each of the multi solar subcells is substantially lattice matched to each of the other solar subcells.

In a second aspect, the present disclosure provides method of preparing a multi junction solar cell comprising: forming a first bottom solar subcell; forming a first junction tunnel; forming a distributed Bragg reflector (DBR) layer; forming a second middle solar subcell; forming a second junction tunnel; and forming a third top solar subcell. The method of forming the multi junction solar cell is Metal-Organic Chemical Vapour Deposition (MOCVD) or Molecular Beam Epitaxy (MBE). The distributed Bragg reflector (DBR) layer has an average lattice parameter greater than the lattice parameter of the second middle solar subcell. Each of the multi solar subcells is substantially lattice matched to each of the other solar subcells.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments consistent with the invention and, together with the description, serve to explain the principles of the invention.

FIG. 1 shows a structural view of a GaAs multi junction solar cell of the present disclosure.

FIG. 2 shows a structural view of DBR of the present disclosure.

FIG. 3 shows the comparison data regarding the wavelength uniformity of an epitaxial wafer top subcell with normal DBR (lattice matched) and an epitaxial wafer top subcell with DBR of the present disclosure (difference between the average lattice parameters of DBR and the second middle solar subcell is greater than zero Å and less than 0.01 Å).

### DETAILED DESCRIPTION

Hereinafter, embodiments of the present disclosure will be described in conjunction with the accompanying drawings, rather than to limit the present disclosure. Variations of structure, method, or functional made by the ordinary skilled in the art based on these examples are all contained in the scope of the present disclosure.

The terms used in present disclosure are merely directed to illustrate the particular examples, rather than limit to the present disclosure. The singular forms “a” “an” and “the” as used in the present disclosure as well as the appended claims also refer to plural forms unless other meanings are definitely contained in the context. It should be appreciated that the term “and/or” as used herein refers to any or all possible combination of one or more associated listed items.

It shall be understood that, although the terms “first,” “second,” “third,” etc. may be used herein to describe various information, the information should not be limited by these terms. These terms are only used to distinguish one category of information from another. For example, without departing from the scope of the present disclosure, first information may be termed as second information; and similarly, second information may also be termed as first information. As used herein, the term “if” may be understood to mean “when” or “upon” or “in response to” depending on the context.

Reference throughout this specification to “one embodiment,” “an embodiment,” “another embodiment,” or the like in the singular or plural means that one or more particular features, structures, or characteristics described in connection with an embodiment is included in at least one embodiment of the present disclosure. Thus, the appearances of the phrases “in one embodiment” or “in an embodiment,” “in another embodiment,” or the like in the singular or plural in various places throughout this specification are not necessarily all referring to the same embodiment. Furthermore, the particular features, structures, or characteristics in one or more embodiments may include combined in any suitable manner.

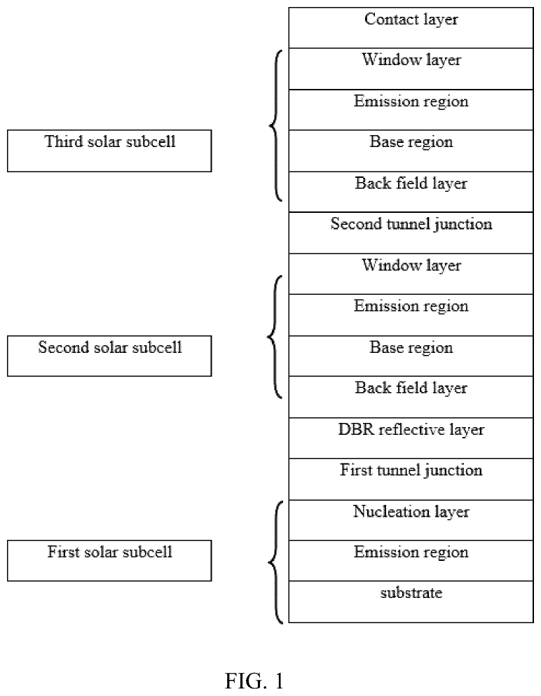

It shall be understood by a person with ordinary skill in the art that some technical terminologies may have some variations. For example, in FIG. 1 or the present disclosure, the term “window layer” may also be referred to as “window”, the term “emission layer” may also be referred to as “emitter”, the term “base region” may be referred to as “base”, the term “back field layer” may be referred to as “back surface field layer (BSF)”, the term “DBR reflective layer” may be referred to as “DBR layers”, and the term “substrate” may be referred to as “Ge substrate”. Such variations may be found throughout this specification.

Some embodiments of the present disclosure will be described in detail with reference to the accompanying drawings. In the case of no conflict, the following embodiments and the features in the embodiments may be combined with each other.

To solve the foregoing mentioned problems of the currently available multi junction solar cells, the present disclosure provides a novel multi junction GaAs solar cells and the manufacturing method thereof. Based on the concept of current DBR layer, the present disclosure introduces or increases the Indium (In) component in the DBR layer in such a manner that the lattice parameter of the DBR layer is greater than that of the middle subcell. Therefore, a compressive stress generated by the lattice mismatch is introduced to balance the tensile stress caused by the thermal mismatch, thereby improving the wavelength and doping uniformity of the middle and top subcells to improve solar cell performance.

The technical solution of the present disclosure is to balances the tensile stress caused by the thermal mismatch by increasing the lattice of the DBR reflective layer to introduce the compressive stress generated by the lattice mismatch, so that the wafer is smooth with neither concave nor convex when growing the middle and the top subcells. The smooth feature of the wafer improves the temperature uniformity on the entire wafer, thereby improves the wavelength uniformity and doping uniformity of the middle and top subcells and improves the solar cell performance.

In one embodiment, the present disclosure provides a multi junction solar cell comprising: a first bottom solar subcell; a second middle solar subcell; a third top solar subcell; a distributed Bragg reflector (DBR) layer, wherein the distributed Bragg reflector (DBR) layer is positioned immediately below the second middle solar subcell, and the distributed Bragg reflector (DBR) layer has an average lattice parameter greater than the lattice parameter of the second middle solar subcell; a first tunnel junction positioned between the first bottom solar subcell and the distributed Bragg reflector (DBR) layer; and a second tunnel junction positioned between the second middle solar subcell and the third top solar subcell. Each of the three solar subcells is substantially lattice matched to each of the other solar subcells.

In one embodiment, the present disclosure provides a multi junction solar cell comprising: a first bottom solar subcell; a second middle solar subcell; a third top solar subcell; a distributed Bragg reflector (DBR) layer, wherein the distributed Bragg reflector (DBR) layer is positioned immediately below the second middle solar subcell, and the distributed Bragg reflector (DBR) layer has an average lattice parameter greater than the lattice parameter of the second middle solar subcell; a first tunnel junction positioned between the first bottom solar subcell and the distributed Bragg reflector (DBR) layer; and a second tunnel junction positioned between the second middle solar subcell and the third top solar subcell.

The distributed Bragg reflector (DBR) layer comprises a plurality of alternating layers of lattice matched materials with discontinuities in their respective indices of refraction and the difference in refractive indices between alternating layers is maximized in order to minimize the number of periods required to achieve a given reflectivity, and the thickness and refractive index of each period determines the stop band and its limiting wavelength, where each of the three solar subcells is substantially lattice matched to each of the other solar subcells.

In one embodiment, the present disclosure provides a multi junction solar cell comprising: a first bottom solar subcell; a second middle solar subcell; a third top solar subcell; a distributed Bragg reflector (DBR) layer, where the distributed Bragg reflector (DBR) layer is positioned immediately below the second middle solar subcell, and the distributed Bragg reflector (DBR) layer has an average lattice parameter greater than the lattice parameter of the second middle solar subcell; a first tunnel junction positioned between the first bottom solar subcell and the distributed Bragg reflector (DBR) layer; and a second tunnel junction positioned between the second middle solar subcell and the third top solar subcell.

In one aspect, the distributed Bragg reflector (DBR) layer comprises a first layer comprising Al, In, Ga, and As, and a second layer comprising In, Ga, and As. Each of the three solar subcells may be substantially lattice matched to each of the other solar subcells.

In one aspect, the distributed Bragg reflector (DBR) layer comprises a first layer comprising Al, In, Ga, and As, and a second layer comprising In, Ga, and As. Each of the three solar subcells may be substantially lattice matched to each of the other solar subcells.

In one embodiment, the present disclosure provides a multi junction solar cell comprising: a first bottom solar subcell; a second middle solar subcell; a third top solar subcell; and a distributed Bragg reflector (DBR) layer. The distributed Bragg reflector (DBR) layer is positioned immediately below the second middle solar subcell, and the distributed Bragg reflector (DBR) layer has an average lattice parameter greater than the lattice parameter of the second middle solar subcell. the difference between the lattice parameters of DBR and the second middle solar subcell is greater than zero Å and less than 0.01 Å (angstrom).A first tunnel junction is positioned between the first bottom solar subcell and the distributed Bragg reflector (DBR) layer. A second tunnel junction is positioned between the second middle solar subcell and the third top solar subcell.

The distributed Bragg reflector (DBR) layer comprises a plurality of repeating units of AlₓInGaAs/Al_{y}InGaAs reflection layers, wherein 0≤y<x≤1, and 0.01≤a≤0.2, In one aspect, 0.01≤a≤0.1, 0.01≤a≤0.09, 0.01≤a≤0.08, 0.01≤a≤0.07, 0.01≤a≤0.06, 0.01≤a≤0.05, 0.01≤a≤0.04, or 0.01≤a≤0.03. In one preferred aspect, 0.01≤a≤0.03.

In one aspect, the distributed Bragg reflector (DBR) layer comprises a plurality of repeating units of AlₓInₐGaAs/Al_{y}InₐGaAs reflection layers, wherein 0≤y<x≤1, 0.01, 0.01≤a≤0.5, 0.01≤a≤0.4, 0.01≤a≤0.3, 0.01≤a≤0.2, 0.01≤a<0.1, 0.01≤a≤0.09, 0.01≤a≤0.08, 0.01≤a≤0.07, 0.01≤a≤0.06, 0.01≤a≤0.05, 0.01≤a≤0.04, or 0.01≤a≤0.03. In one preferred aspect, 0.01≤a≤0.03.

In one embodiment, the present disclosure provides a multi junction solar cell comprising: a first bottom solar subcell; a second middle solar subcell; a third top solar subcell; a distributed Bragg reflector (DBR) layer, wherein the distributed Bragg reflector (DBR) layer is positioned immediately below the second middle solar subcell, and the distributed Bragg reflector (DBR) layer has an average lattice parameter greater than the lattice parameter of the second middle solar subcell; a first tunnel junction positioned between the first bottom solar subcell and the distributed Bragg reflector (DBR) layer; and a second tunnel junction positioned between the second middle solar subcell and the third top solar subcell.

The distributed Bragg reflector (DBR) layer comprises a plurality of repeating units of AlxInGaAs/AlyInGaAs reflection layers, wherein 0≤y<x≤1, AlyInGaAs layer is disposed on AlxInGaAs layer in each repeating unit. Each of the three solar subcells may be substantially lattice matched to each of the other solar subcells.

The distributed Bragg reflector (DBR) layer comprises a plurality of repeating units of AlxInGaAs/AlyInGaAs reflection layers, wherein 0≤y<x≤1, AlyInGaAs layer is disposed on AlxInGaAs layer in each repeating unit. Each of the three solar subcells may be substantially lattice matched to each of the other solar subcells.

In one embodiment regarding the multi junction solar cell of the present disclosure, the distributed Bragg reflector (DBR) layer has an average lattice parameter greater than the lattice parameter of the second middle solar subcell, and the difference between the lattice parameters of DBR and the second middle solar subcell is greater than zero Å and less than 0.1 Å (angstrom), greater than zero Å and less than 0.09 Å, greater than zero Å and less than 0.08 Å, greater than zero Å and less than 0.07 Å, greater than zero Å and less than 0.06 Å, greater than zero Å and less than 0.05 Å, greater than zero Å and less than 0.04 Å, greater than zero Å and less than 0.03 Å, greater than zero Å and less than 0.02 Å, or greater than zero Å and less than 0.01 Å. In one preferred aspect, the difference between the lattice parameters is greater than zero Å and less than 0.01 Å. If the difference between the lattice parameters of DBR and the second middle solar subcell is too much, it may lead to overly big lattice mismatch, which may cause dislocation.

In one embodiment regarding the multi junction solar cell of the present disclosure, the distributed Bragg reflector (DBR) layer comprises a double-layer unit, wherein the double-layer unit comprises a first layer comprising Al, In, Ga, and As, and a second layer comprising In, Ga, and As. In one aspect, the second layer comprise Al. In, Ga, and As. In one aspect, the second layer is disposed on the first layer.

In one embodiment regarding the multi junction solar cell of the present disclosure, the distributed Bragg reflector (DBR) layer comprises 5-100, 5-90, 5-80, 5-70, 5-60, or 5-50 periods of alternating material pairs.

In one embodiment regarding the multi junction solar cell of the present disclosure, the thickness of the alternating layers of the distributed Bragg reflector (DBR) layer is configured so that the center of the DBR reflectivity peak is resonant with the absorption wavelength of the low band gap layers formed in the intrinsic layer of the middle subcell of the three-junction solar cell.

In one embodiment regarding the multi junction solar cell of the present disclosure, the preferred multi junction solar cell is a three-junction solar cell.

In one embodiment regarding the multi junction solar cell of the present disclosure, the repeating units of AlₓInGaAs/Al_{y}InGaAs reflection layers of the DBR layer are configured such that said Al_{y}InGaAs is deposited on top of said AlₓInGaAs in each unit of the AlₓInGaAs/Al_{y}InGaAs reflection layer.

In one embodiment regarding the multi junction solar cell of the present disclosure, each AlₓInGaAs/Al_{y}InGaAs reflection layer has an optical thickness of ¼ wavelength of a center reflecting light.

In one embodiment regarding the multi junction solar cell of the present disclosure, the first bottom solar subcell is a Ge solar subcell.

In one embodiment regarding the multi junction solar cell of the present disclosure, the second middle solar subcell is an InGaAs solar subcell.

In one embodiment regarding the multi junction solar cell of the present disclosure, the third top solar subcell is a GaInP solar subcell.

In one embodiment regarding the multi junction solar cell of the present disclosure, the third top solar subcell is an AlGaInP solar subcell.

In one embodiment regarding the multi junction solar cell of the present disclosure, the second middle solar subcell is an In_{0.01}GaAs solar subcell, and the distributed Bragg reflector (DBR) layer has an average lattice parameter greater than the lattice parameter of the In_{0.01}GaAs solar subcell.

In one embodiment regarding the multi junction solar cell of the present disclosure, the second middle solar subcell is an In_{0.01}GaAs solar subcell having a lattice parameter of 0.5673 nm, and the distributed Bragg reflector (DBR) layer has an average lattice parameter greater than 0.5673 nm.

In one embodiment regarding the multi junction solar cell of the present disclosure, the first bottom solar subcell is Ge solar subcell; the second middle solar subcell is an InGaAs solar subcell; and the third top solar subcell is a GaInP solar subcell.

In one embodiment regarding the multi junction solar cell of the present disclosure, the first bottom solar subcell is Ge solar subcell; the second middle solar subcell is an InGaAs solar subcell; and the third top solar subcell is an AlGaInP solar subcell.

In one embodiment regarding the multi junction solar cell of the present disclosure, the first bottom solar subcell is Ge solar subcell; the second middle solar subcell is an In_{0.01}GaAs solar subcell; the third top solar subcell is an AlGaInP solar subcell, wherein the distributed Bragg reflector (DBR) layer has an average lattice parameter greater than the lattice parameter of the In_{0.01}GaAs solar subcell.

In one embodiment regarding the multi junction solar cell of the present disclosure, the first bottom solar subcell is Ge solar subcell; the second middle solar subcell is an In_{0.01}GaAs solar subcell; the third top solar subcell is an AlGaInP solar subcell, wherein the distributed Bragg reflector (DBR) layer has an average lattice parameter greater than 0.5673 nm.

In one embodiment regarding the multi junction solar cell of the present disclosure, one additional protecting layer between the DBR layer and the first tunnel junction is provided for the purpose of protecting the first tunnel junction such that the stress caused by the thermal mismatch by increasing the lattice of the DBR reflective layer will not negatively impact the first tunnel junction. In addition, the additional protecting layer may also improve the interface between the DBR layer and the first tunnel junction. In one aspect, the additional protecting layer comprises InₓGaAs, wherein 0≤x≤0.015. In one aspect, the additional protecting layer has a thickness of about 50-500 nm.

In one embodiment, the present disclosure provides method of preparing a multi junction solar cell comprising: forming a first bottom solar subcell; forming a first junction tunnel; forming a distributed Bragg reflector (DBR) layer; forming a second middle solar subcell; forming a second junction tunnel; and forming a third top solar subcell. The method of forming the multi junction solar cell may be but is not limited to Metal-Organic Chemical Vapour Deposition (MOCVD) or Molecular Beam Epitaxy (MBE). The distributed Bragg reflector (DBR) layer has an average lattice parameter greater than the lattice parameter of the second middle solar subcell. Each of the three solar subcells is substantially lattice matched to each of the other solar subcells.

In one embodiment, the present disclosure provides method of preparing a multi junction solar cell. The method may include at least following steps: forming a first bottom solar subcell; forming a first junction tunnel; forming a distributed Bragg reflector (DBR) layer;

forming a second middle solar subcell; forming a second junction tunnel; and forming a third top solar subcell.

The method of forming the multi junction solar cell is Metal-Organic Chemical Vapor Deposition (MOCVD) or Molecular Beam Epitaxy (MBE). The distributed Bragg reflector (DBR) layer comprises a plurality of repeating units of AlₓInGaAs/Al_{y}InGaAs reflection layers, wherein 0≤y<x≤1. Each of the multi solar subcells is substantially lattice matched to each of the other solar subcells.

In one embodiment regarding the method of preparing a multi junction solar cell of the present disclosure, the distributed Bragg reflector (DBR) layer has an average lattice parameter greater than the lattice parameter of the second middle solar subcell.

In one embodiment regarding the method of preparing a multi junction solar cell of the present disclosure, the first bottom solar subcell is Ge solar subcell; the second middle solar subcell is an InGaAs solar subcell; and the third top solar subcell is a GaInP solar subcell.

In one embodiment regarding the method of preparing a multi junction solar cell of the present disclosure, the first bottom solar subcell is Ge solar subcell; the second middle solar subcell is an InGaAs solar subcell; and the third top solar subcell is an AlGaInP solar subcell.

In one embodiment regarding the method of preparing a multi junction solar cell of the present disclosure, the first bottom solar subcell is Ge solar subcell; the second middle solar subcell is an In_{0.01}GaAs solar subcell; and the third top solar subcell is a GaInP solar subcell or an AlGaInP solar subcell.

In one embodiment regarding the method of preparing a multi junction solar cell of the present disclosure, the second middle solar subcell is an In_{0.01}GaAs solar subcell, and the distributed Bragg reflector (DBR) layer has an average lattice parameter greater than the lattice parameter of the In_{0.01}GaAs solar subcell.

In one embodiment regarding the method of preparing a multi junction solar cell of the present disclosure, the second middle solar subcell is an In_{0.01}GaAs solar subcell having a lattice parameter of 0.5673 nm, and the distributed Bragg reflector (DBR) layer has an average lattice parameter greater than 0.5673 nm.

In one embodiment regarding the method of preparing a multi junction solar cell of the present disclosure, the repeating units of AlₓInGaAs/AlyInGaAs reflection layers are configured such that said AlyInGaAs is deposited on top of said AlₓInGaAs in each unit of the AlₓInGaAs/AlyInGaAs reflection layer.

In one embodiment regarding the method of preparing a multi junction solar cell of the present disclosure, each AlyInGaAs reflection layer has an optical thickness of ¼ wavelength of a center reflecting light.

In one embodiment regarding the method of preparing a multi junction solar cell of the present disclosure, more specifically in the process of fabricating DBR layer, in order to improve the heterojunction quality of the alternative layers, such as the AlₓIn_{y}GaAs layer and InGaAs layer, in the MOCVD growth process, the growth pause time for the hetero interface between AlₓIn_{y}GaAs layer and InGaAs is applied and the growth pause time is controlled between about 0.5-10 s. In one aspect, the growth pause time is about 1-10, 1-9, 1-8, 1-7, 1-6, 1-5, 2-10, 2-9, 2-8, 2-7, 2-6, 2-5 s. In one preferred aspect, the growth pause time is about 2-5 s.

In one embodiment regarding the method of preparing a multi junction solar cell of the present disclosure, wherein the method further comprises a step of forming one additional protecting layer between the DBR layer and the first tunnel junction. In one aspect, the additional protecting layer comprises InₓGaAs, wherein 0≤x≤0.015. In one aspect, the additional protecting layer has a thickness of about 50-500 nm

In conjunction with the figures and exemplary embodiments, the technical solutions in the embodiments of the present disclosure will be clearly and completely described. Obviously, the described embodiments are merely part of embodiments of the present disclosure, rather than all embodiments. Any embodiment obtained by those of ordinary skill in the art is within the scope of protection of the present application if such embodiment does not involve any inventive step in view of the present disclosure.

One of the key features of the present disclosure and the point of protection are based on the introduction of the DBR reflective layer into the middle subcell of the GaInP/InGaAs/Ge multi-junction cell, and make the lattice parameter of the DBR reflective layer greater than the lattice parameter of the middle subcell. On the contrary, the prior art adopted a structure in which the lattice parameters of the DBR and the middle subcell must match each other.

As illustrated in FIG. 1, the GaInP/InGaAs/Ge multi junction solar cell described as the embodiment of the present disclosure is grown on a Ge substrate by Metal-Organic Chemical Vapour Deposition (MOCVD) or Molecular Beam Epitaxy (MBE). From the bottom to the top, the multi junction solar cell comprises a first subcell, a first tunnel junction, a DBR reflective layer, a second sub-cell, a second tunnel junction, and a third sub-cell, wherein the multi sub-cells are lattice-matched and connected by the tunnel junctions. In this exemplified embodiment, the first subcell is a bottom Ge subcell, the second subcell is a middle InGaAs subcell, and the third subcell is a top (Al) GaInP subcell. The expression (Al) in any of the composition in the present disclosure means that Al is an optional component.

Phosphorus diffusion on a p-type Ge substrate provided an n-type emitter region and a pn junction of the first subcell. A nucleation layer, which also functioned as the window layer of the first bottom subcell, was formed by growing (Al) GaInP layer on the on the p-type Ge substrate, wherein the lattice of (Al) GaInP layer and p-type Ge substrate matched each other.

An n-type GaAs or n -type GaInP is then formed as the N-type layer of the first tunnel junction, and a p-type (Al) GaAs material is formed as the P-type layer of the first tunnel junction. The N-type and P-type dopings are doped with Si and C, respectively.

A DBR reflective layer of AlₓInGaAs/Al_{y}InGaAs is further formed, in which 0≤y<x≤1. The average lattice parameter of DBR layer is greater than the lattice parameter of the middle layer. The difference of the average lattice parameter is greater than zero and less than 0.01 Å. Such a difference is critical to provide the desired multi junction solar cell.

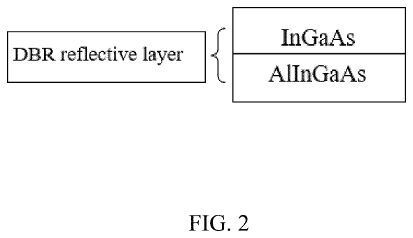

The DBR layer is composed of n units of AlₓInGaAs/AlyInGaAs as illustrated in FIG. 2, wherein the optical thickness of each layer of material is about ¼ wavelength of a center reflecting light, and wherein n is greater than 5 and less than 25. It should be recognized that FIG. 2 is only a simplified and non-limiting expression of a DBR that does not include all the possible components/compositions that have been disclosed in the present disclosure.

The second subcell comprises, in an order from bottom to top, a back field layer, a p-type doped InGaAs layer as base region, an n-type doped InGaAs layer as emission region, and a window layer. The back field layer comprises GaInP or AlGaAs material, and the window layer comprises AlGaInP or AlInP material.

n-Type GaAs or n-type GaInP is formed as the N-type layer of the second tunnel junction; and p-type (Al) GaAs is formed as the P-type layer of the second tunnel junction. The N -type and P -type dopings are doped with Si and C, respectively.

The third subcell comprises, in an order from bottom to top, an AlGaInP back field layer, a p-type doped AlGaInP or GaInP layer as base region, an n-type doped AlGaInP or GaInP layer as emission region, and an AlInP window layer.

Finally, a GaAs or InGaAs layer is formed as an N-type contact layer that forms an ohmic contact with the electrode.

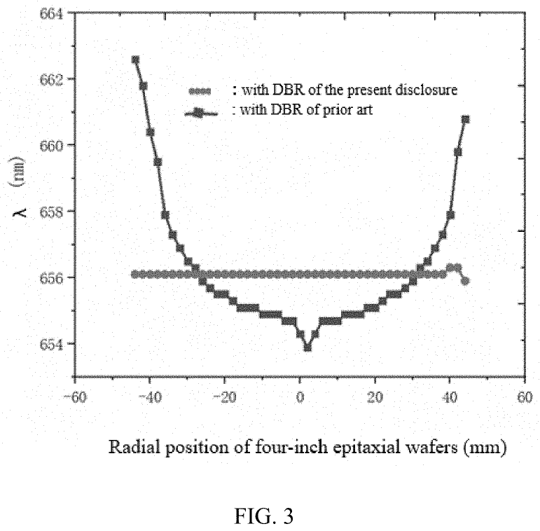

FIG. 3 shows the comparison data regarding the wavelength uniformity of the normal DBR (the average lattice parameter of DBR is substantially the same as the lattice parameter of the middle solar subcell) and the DBR of the present disclosure (the average lattice parameter of DBR is greater than the lattice parameter of the middle solar subcell. The difference of the average lattice parameter is greater than zero and less than 0.01 Å.). The results were obtained through photoluminescence test with epitaxial wafer top subcell with different DBR. FIG. 3 clear demonstrated the significant improvement of the new DBR of the present disclosure for the wavelength uniformity for the top solar subcell. The normal DBR provided uneven wavelengths between a wavelength range of about 654 nm to about 664 nm. However, the DBR of the present disclosure provided almost constant wavelength around 656 nm. The wavelength uniformity STD value is 0.239 nm for the DBR of the present disclosure, and the comparative wavelength uniformity STD value obtained by normal DBR is 2.235 nm. Such an improvement is clearly unexpected.

In summary, the present disclosure provides a novel multi junction GaAs solar cells and the manufacturing method thereof. Based on the concept of current DBR layer, the present disclosure introduces or increases the Indium (In) component in the DBR layer in such a manner that the lattice parameter of the DBR layer is greater than that of the middle subcell. Therefore, a compressive stress generated by the lattice mismatch is introduced to balance the tensile stress caused by the thermal mismatch, thereby improving the wavelength and doping uniformity of the middle and top subcells to improve solar cell performance.

The technical solution of the present disclosure balances the tensile stress caused by the thermal mismatch by increasing the lattice of the DBR reflective layer to introduce the compressive stress generated by the lattice mismatch, so that the wafer is smooth with neither concave nor convex when growing the middle and the top subcells. The smooth feature of the wafer improves the temperature uniformity on the entire wafer, thereby improving the wavelength uniformity and doping uniformity of the middle and top subcells and improving the solar cell performance.

Other embodiments of the invention will be apparent to those skilled in the art from consideration of the specification and practice of the invention disclosed here. This application is intended to cover any variations, uses, or adaptations of the invention following the general principles thereof and including such departures from the present disclosure as come within known or customary practice in the art. It is intended that the specification and examples be considered as exemplary only, with a true scope and spirit of the invention being indicated by the following claims.

It will be appreciated that the present invention is not limited to the exact examples described above and illustrated in the accompanying drawings, and that various modifications and changes can be made without departing from the scope thereof. It is intended that the scope of the invention only be limited by the appended claims.

What is claimed is:

1. A multi junction solar cell comprising:
a first bottom solar subcell;
a second middle solar subcell;
a third top solar subcell;
a distributed Bragg reflector (DBR) layer, wherein the distributed Bragg reflector (DBR) layer is positioned immediately below the second middle solar subcell, and the distributed Bragg reflector (DBR) layer has an average lattice parameter greater than the lattice parameter of the second middle solar subcell;
a first tunnel junction positioned between the first bottom solar subcell and the distributed Bragg reflector (DBR) layer; and
a second tunnel junction positioned between the second middle solar subcell and the third top solar subcell;
wherein each of the three solar subcells is substantially lattice matched to each of the other solar subcells.

2. The multi junction solar cell of claim 1, wherein the distributed Bragg reflector (DBR) layer comprises a first layer comprising Al, In, Ga, and As, and a second layer comprising In, Ga, and As.

3. The multi junction solar cell of claim 1, wherein the distributed Bragg reflector (DBR) layer comprises a plurality of repeating units of AlₓInGaAs/Al_{y}InGaAs reflection layers, wherein 0≤y<x≤1.

4. The multi junction solar cell of claim 1, wherein AlₓInGaAs layer is disposed on Al_{y}InGaAs layer in each repeating unit.

5. The multi junction solar cell of claim 1, wherein the average lattice parameter difference between DBR and the second middle solar subcell is greater than zero Å and less than 0.01 Å.

6. The multi junction solar cell of claim 1, wherein the first bottom solar subcell is a Ge solar subcell.

7. The multi junction solar cell of claim 1, wherein the second middle solar subcell is an InGaAs solar subcell.

8. The multi junction solar cell of claim 1, wherein the third top solar subcell is a (Al)GaInP solar subcell.

9. The multi junction solar cell of claim 1, wherein the first bottom solar subcell is Ge solar subcell; the second middle solar subcell is an InGaAs solar subcell; and the third top solar subcell is a (Al)GaInP solar subcell.

10. The multi junction solar cell of claim 1, further comprising one additional protecting layer between the DBR layer and the first tunnel junction.

11. The multi junction solar cell of claim 10, wherein the additional protecting layer comprises InₓGaAs, and wherein 0≤x≤0.015.

12. The multi junction solar cell of claim 10, wherein the additional protecting layer has a thickness of 50-500 nm.

13. A method of preparing a multi junction solar cell comprising:
forming a first bottom solar subcell;
forming a first junction tunnel;
forming a distributed Bragg reflector (DBR) layer;
forming a second middle solar subcell;
forming a second junction tunnel; and
forming a third top solar subcell;
wherein the distributed Bragg reflector (DBR) layer has an average lattice parameter greater than the lattice parameter of the second middle solar subcell,
wherein each of the three solar subcells is substantially lattice matched to each of the other solar subcells.

14. The method of claim 13, wherein the distributed Bragg reflector (DBR) layer comprises a first layer comprising Al, In, Ga, and As, and a second layer comprising In, Ga, and As.

15. The method of claim 13, wherein the distributed Bragg reflector (DBR) layer comprises a plurality of repeating units of AlₓInGaAs/Al_{y}InGaAs reflection layers, wherein 0≤y<x≤1.

16. The method of claim 13, wherein the lattice parameter difference between DBR and the second middle solar subcell is greater than zero Å and less than 0.01 Å.

17. The method of claim 13, wherein a growth pause time for hetero interface between is controlled between 2-5 s.

18. The method of claim 13, further comprising forming one additional protecting layer between the DBR layer and the first tunnel junction.

19. The method of claim 18, wherein the additional protecting layer comprises InₓGaAs, and wherein 0≤x≤0.015.

20. The method of claim 18, wherein the additional protecting layer has a thickness of 50-500 nm.
